(19) United States
(12) Patent Application Publication
(10) Pub. No.: US 2024/0413841 A1
(43) Pub. Date: Dec. 12, 2024

(54) APPARATUSES AND METHODS FOR ECC PARITY BIT REDUCTION

(71) Applicant: Micron Technology, Inc., Boise, ID (US)

(72) Inventors: Jiyun Li, Boise, ID (US); Toby D. Robbs, Boise, ID (US)

(73) Assignee: Micron Technology, Inc., Boise, ID (US)

(21) Appl. No.: 18/738,499

(22) Filed: Jun. 10, 2024

Related U.S. Application Data
(60) Provisional application No. 63/507,608, filed on Jun. 12, 2023.

(51) Int. Cl. H03M 13/11; H03M 13/00

(52) U.S. Cl. CPC H03M 13/1105; H03M 13/1148; H03M 13/6505

(57) ABSTRACT

Apparatuses and methods for on-device error correction implemented in a memory. A memory may have a first column plane comprising a first number of bit lines and a parity column plane that has a second number of parity bit lines in which the first number is different than the second number. In an access operation, a column select signal may activate the first number of bit lines in the first column plane and the second number of parity bit lines in the second column plane.

### CROSS REFERENCE TO RELATED APPLICATION(S)

This application claims priority to U.S. Provisional Application No. 63/507,608, filed Jun. 12, 2023. The aforementioned application is incorporated herein by reference, in its entirety, for any purpose.

### BACKGROUND

This disclosure relates generally to semiconductor devices, and more specifically to semiconductor memory devices. In particular, the disclosure relates to volatile memory, such as dynamic random access memory (DRAM). Information may be stored on individual memory cells of the memory as a physical signal (e.g., a charge on a capacitive element). During an access operation, an access command may be received along with address information which specifies which memory cells should be accessed.

Some memories may include on-device error correction. In such devices, the memory array may generate parity bits when data is written to the array, and then during a read operation use those parity bits to check the data for errors. The number of errors which can be detected and/or corrected may be based, in part, on the number of parity bits. However, these parity bits may take up space in the array. It may be desirable to ensure that only the necessary number of parity bits for a given level of correction are stored in the array. It may be desirable to have alternative approaches to performing error correcting functions in semiconductor devices.

### BRIEF DESCRIPTION OF THE SEVERAL VIEWS OF THE DRAWINGS

FIG. 1 is a block diagram of an apparatus according to some embodiments of the disclosure.

FIG. 2 is a block diagram of a memory device according to some embodiments of the present disclosure.

FIG. 3 shows a data column plane according to an embodiment of the disclosure.

FIG. 4 shows a parity column plane according to an embodiment of the disclosure. illustrates an aspect of the subject matter in accordance with one embodiment.

FIG. 5 illustrates a flow chart of a method according to some embodiments of the present disclosure.

### DETAILED DESCRIPTION

Certain details are set forth below to provide a sufficient understanding of embodiments of the disclosure. However, it will be clear to one having skill in the art that embodiments of the disclosure may be practiced without these particular details. Moreover, the particular embodiments of the disclosure described herein should not be construed to limit the scope of the disclosure to these particular embodiments. In other instances, well-known circuits, control signals, timing protocols, and software operations have not been shown in detail in order to avoid unnecessarily obscuring embodiments of the disclosure. Additionally, terms such as “couples” and “coupled” mean that two components may be directly or indirectly electrically coupled. Indirectly coupled may imply that two components are coupled through one or more intermediate components.

A memory device may include a memory array which has a number of memory cells, each located at the intersection of a word line (row) and digit line or bit line (column). During a read or write operation, a row may be activated, and data may be read from, or written to, the memory cells along the activated row. Each row may include memory cells which store a number of bits of data and a number of bits of parity information (e.g., data bits and parity bits), which may be used to correct up to a certain number of errors in the data bits. For example, a row may include i data bits and k parity bits, which may be used to correct up to j of the data bits. During a write operation the parity bits may be generated by an error correction circuit based on the data written to the memory cells of the row. During a read operation the error correction circuit may use the parity bits to determine if the read data bits are correct, and may correct any errors which are found.

The memory array may be arranged into column planes, each of which includes a number of sets of digit lines. Each set of digit lines is accessed by a common value of a column select (CS) signal. For example, a value of the CS signal may access 8 digit lines, and therefore 8 bits may be accessed from each column plane for a given value of the CS signal. The array may be organized such that data is stored in column planes set aside for data storage (e.g., data column planes) and the parity bits are stored in column planes set aside for parity storage (e.g., parity column planes). During a write operation, an error correction code (ECC) circuit may generate parity bits based on the received data, and during a read operation, the ECC circuit may use the data and parity to detect and/or correct errors in the data. The number of bits of error which may be detected/corrected may be based on the number of data bits and the number of parity bits.

In a conventional memory device, there may be sixteen data column planes and a single parity column plane for a total of 128 data bits and 8 parity bits. However, certain data architectures allow for increased numbered of data and parity column planes. For example, an XXX architecture includes thirty-two data column planes (e.g., 256 data bits) and 2 parity column planes (e.g., 16 parity bits). This may be inefficient, as many ECC implementations such as single error correction (SEC) may use fewer parity bits for that many data bits. There may be a need to have parity column planes which have different access architecture than the data column planes in order to better match data and parity.

The present disclosure is drawn to apparatuses, systems and methods for ECC parity bit storage reduction. Responsive to a value of the CS signal, a first number of bit lines may be accessed in a first column plane (e.g., a data column plane) and a second number of bit lines may be accessed in a second column plane (e.g., a parity column plane). This may allow a more efficient match between the number of accessed parity bits and the number used by the ECC circuit, as the number of used parity bits may not be a multiple of the sample number of bits lines accessed in each data column plane (e.g., 8). For example, if there are 32 data column planes, and in each data column plane 8 bits of data are accessed for a value of the CS signal (for a total of 256 data bits) then there may be 2 parity column planes in which the CS signal accesses 6 bits (for a total of 12 parity bits). This may allow for a space savings, as the parity column plane may store the parity bits more efficiently, and may have a reduced number of memory cells (e.g., a reduced size) compared to if it used the same number of bit lines per CS signal as the data column planes.

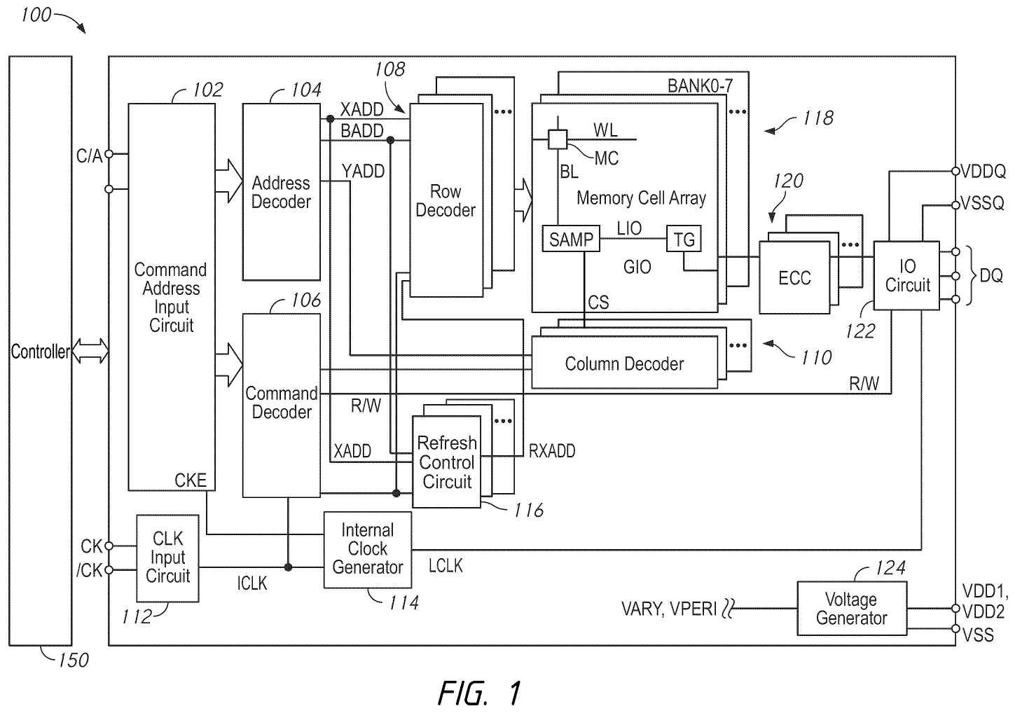

FIG. 1 is a block diagram of an apparatus according to an embodiment of the disclosure. The apparatus may be a semiconductor device 100, and will be referred to as such. In some embodiments, the semiconductor device 100 may include, without limitation, a DRAM device, such as low power DDR (LPDDR) memory integrated into a single semiconductor chip, for example.

The semiconductor device 100 includes a memory array 118. The memory array 118 is shown as including a plurality of memory banks. In the embodiment of FIG. 1, the memory array 118 is shown as including eight memory banks BANK0-BANK7. More or fewer banks may be included in the memory array 118 of other embodiments. Each memory bank includes a plurality of word lines WL, a plurality of bit lines BL, and a plurality of memory cells MC arranged at intersections of the plurality of word lines WL and the plurality of bit line BL. The selection of the word line WL is performed by a row decoder 108 and the selection of the bit lines BL is performed by a column decoder 110. In the embodiment of FIG. 1, the row decoder 108 includes a respective row decoder for each memory bank and the column decoder 110 includes a respective column decoder for each memory bank. The bit lines BL are coupled to a respective sense amplifier (SAMP). Read data from the bit line BL is amplified by the sense amplifier SAMP, and transferred to read/write amplifiers over complementary local data lines (LIOT/B), transfer gate (TG), and complementary main data lines (MIOT/B) or global data lines (GIO) which are coupled to an error correction code (ECC) control circuit 120. Conversely, write data outputted from the ECC control circuit 120 is transferred to the sense amplifier SAMP over the complementary main data lines MIOT/B or global data lines (GIO), the transfer gate TG, and the complementary local data lines LIOT/B, and written in the memory cell MC coupled to the bit line BL.

The semiconductor device 100 may employ a plurality of external terminals that include command and address (C/A) terminals coupled to a command and address bus to receive commands and addresses, and a CS signal, clock terminals to receive clocks CK and/CK, data terminals DQ to provide data, and power supply terminals to receive power supply potentials VDD, VSS, VDDQ, and VSSQ.

The clock terminals are supplied with external clocks CK and/CK that are provided to an input circuit 112. The external clocks may be complementary. The input circuit 112 generates an internal clock ICLK based on the CK and/CK clocks. The ICLK clock is provided to the command decoder 106 and to an internal clock generator 114. The internal clock generator 114 provides various internal clocks LCLK based on the ICLK clock. The LCLK clocks may be used for timing operation of various internal circuits. The internal data clocks LCLK are provided to the input/output circuit 122 to time operation of circuits included in the input/output circuit 122, for example, to data receivers to time the receipt of write data.

The C/A terminals may be supplied with memory addresses. The memory addresses supplied to the C/A terminals are transferred, via a command/address input circuit 102, to an address decoder 104. The address decoder 104 receives the address and supplies a decoded row address XADD to the row decoder 108 and supplies a decoded column address YADD to the column decoder 110. The address decoder 104 may also supply a decoded bank address BADD, which may indicate the bank of the memory array 118 containing the decoded row address XADD and column address YADD. The C/A terminals may be supplied with commands. Examples of commands include timing commands for controlling the timing of various operations, access commands for accessing the memory, such as read commands for performing read operations and write commands for performing write operations, as well as other commands and operations. The access commands may be associated with one or more row address XADD, column address YADD, and bank address BADD to indicate the memory cell(s) to be accessed.

The commands may be provided as internal command signals to a command decoder 106 via the command/address input circuit 102. The command decoder 106 includes circuits to decode the internal command signals to generate various internal signals and commands for performing operations. For example, the command decoder 106 may provide a row command signal to select a word line and a column command signal to select a bit line.

The device 100 may receive an access command which is a read command. When a read command is received, and a bank address, a row address and a column address are timely supplied with the read command, read data is read from memory cells in the memory array 118 corresponding to the row address and column address. The read command is received by the command decoder 106, which provides internal commands so that read data from the memory array 118 is provided to the ECC control circuit 120. The read command may also cause one or more parity bits associated with the read data to be provided along the MIOT/B to the ECC control circuit 120. The ECC control circuit 120 may use the parity bits to determine if the read data includes any errors, and if any errors are detected, may correct them to generate corrected read data. The corrected read data is output to outside the device 100 from the data terminals DQ via the input/output circuit 122.

The device 100 may receive an access command which is a write command. When the write command is received, and a bank address, a row address and a column address are timely supplied with the write command, and write data is supplied through the DQ terminals to the ECC control circuit 120. The write data supplied to the data terminals DQ is written to a memory cells in the memory array 118 corresponding to the row address and column address. The write command is received by the command decoder 106, which provides internal commands so that the write data is received by data receivers in the input/output circuit 122. Write clocks may also be provided to the external clock terminals for timing the receipt of the write data by the data receivers of the input/output circuit 122. The write data is supplied via the input/output circuit 122 to the ECC control circuit 120. The ECC control circuit 120 may generate a number of parity bits based on the write data, and the write data and the parity bits may be provided to the memory array 118 to be written into the memory cells MC. In an example, the number of parity bits may be fewer than the number of bit lines BL.

The ECC control circuit 120 may be used to ensure the fidelity of the data read from a particular group of memory cells to the data written to that group of memory cells. The device 100 may include a number of different ECC control circuits 120, each of which is responsible for a different portion of the memory cells MC of the memory array 118. For example, there may be one or more ECC control circuits 120 for each bank of the memory array 118. As part of a given access operation, each ECC control circuit 120 may be responsible for reading/writing data to memory cells of the memory array 118 which are not adjacent to each other. For example, when a row is activated and data is coupled between a portion of the memory cells of the activated row and an ECC control circuit 120, between all of the memory cells coupled to the ECC circuit 120 there may be at least one other memory cell which is not coupled to that ECC circuit 120.

In some embodiments, different groups of data (and parity bits) may be provided to (or read from) non-adjacent memory cells in parallel. For example, a first ECC control circuit 120 may handle one first group of memory cells, while a second ECC control circuit 120 handles a second group of memory cells. Memory cells in the first group of memory cells are not adjacent to other memory cells in the first group of memory cells, and memory cells in the second group of memory cells are not adjacent to other memory cells of the second group of memory cells, although memory cells of the first group may be adjacent to memory cells of the second group. For example, an ‘even’ ECC control circuit may handle memory cells coupled to even numbered digit lines, while an ‘odd’ ECC control circuit may handle memory cells coupled to odd numbered digit lines.

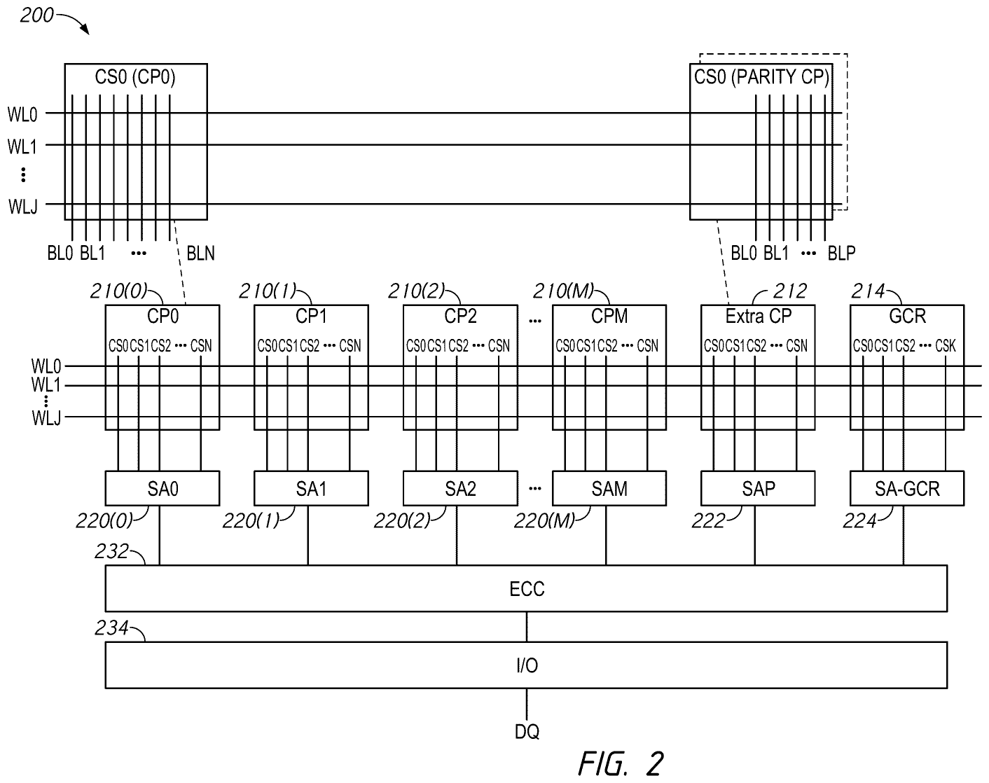

Each ECC control circuit 120 may receive a certain number of data bits (either from the IO circuit 122 or the memory array 118) and may use a number of parity bits based on the number of data bits to correct potential errors in the data bits. A conventional semiconductor (e.g. LPDDR5) may use 256 parallel data bits and an ECC control circuit may generate 16 parity bits based on the data bits. Hammering code single error correction includes 9 parity bits thus it may support 511 bits (502 data bits+9 parity bits). This may be wasteful because a column plane is 8 bit wide. 9 parity bits may require a minimum of 2 parity column planes. In an example embodiment, as part of a write operation an ECC control circuit 120 may receive 256 bits of data from the IO circuit and may generate 12 parity bits based on those 256 data bits. The 256 data bits may be divided into respective column planes each comprising column sets, each column set comprising 8 bit lines, and two parity column planes each comprising column sets, each column set comprising 6 parity bits may be written to the memory array 118. As part of an example read operation, the ECC control circuit 120 may receive 256 data bits and 12 parity bits from the memory cell array 118. The ECC control circuit 120 may use the 12 parity bits to determine if there are any errors in the 256 read data bits, and may correct them if any are found. For example, the ECC control circuit 120 may be able to locate and correct up to one error in the 128 data bits based on the 6 parity bits. While various embodiments may be discussed with reference to ECC circuits which use 6 parity bits to find one error in 128 data bits, it should be understood that these are for explanatory purposes only, and that other numbers of data bits, error bits, and parity bits may be used in other example embodiments. An example ECC circuit is discussed in more detail in FIG. 2.

In some embodiments, the device 100 may operate in different modes, which may, in part, determine how the ECC control circuits 120 are coupled to the memory cells MC of the memory array 118. In some embodiments, the different modes may determine how many of the DQ pads are used as part of a given access operation. For example, as part of an x16 operation mode, 16 different DQ pads may be used. Data may be burst-written to the memory with each pad receiving a burst of 16 bits of data, for a total of 256 bits which may then be written into the memory array 118. In the x16 operation mode, when data is read, 256 bits may be read from the memory array 118 and then provided as 16 bursts of 16 bits each to the DQ pads. In another example, as part of an x8 operation mode, 8 different DQ pads may be used. Each of the DQ pads may still receive (or provide) bursts of 16 bits each, but the device may handle 128 bits as part of a single burst. In some embodiments, the device 100 may still read or write 256 bits at a time to the memory array 118, but may receive (or provide) it as part of two bursts of 128 bits each. While various embodiments will be discussed with reference to x16 and x8 modes of operation, it should be understood that these are intended as examples, and that the concepts and embodiments described herein are not limited to any particular number of DQ terminals, burst length, etc.

The device 100 may also receive commands causing it to carry out one or more refresh operations as part of a self-refresh mode. In some embodiments, the self-refresh mode command may be externally issued to the memory device 100. In some embodiments, the self-refresh mode command may be periodically generated by a component of the device. In some embodiments, when an external signal indicates a self-refresh entry command, the refresh signal AREF may also be activated. The refresh signal AREF may be a pulse signal which is activated when the command decoder 106 receives a signal which indicates entry to the self-refresh mode. The refresh signal AREF may be activated once immediately after command input, and thereafter may be cyclically activated at desired internal timing. The refresh signal AREF may be used to control the timing of refresh operations during the self-refresh mode. Thus, refresh operations may continue automatically. A self-refresh exit command may cause the automatic activation of the refresh signal AREF to stop and return to an IDLE state. The refresh signal AREF is supplied to the refresh control circuit 116. The refresh control circuit 116 supplies a refresh row address RXADD to the row decoder 108, which may refresh one or more wordlines WL indicated by the refresh row address RXADD.

The power supply terminals are supplied with power supply potentials VDD and VSS. The power supply potentials VDD and VSS are supplied to an internal voltage generator circuit 124. The internal voltage generator circuit 124 generates various internal potentials VPP, VOD, VARY, VPERI, and the like based on the power supply potentials VDD and VSS supplied to the power supply terminals. The internal potential VPP is mainly used in the row decoder 108, the internal potentials VOD and VARY are mainly used in the sense amplifiers SAMP included in the memory array 118, and the internal potential VPERI is used in many peripheral circuit blocks.

The power supply terminals are also supplied with power supply potentials VDDQ and VSSQ. The power supply potentials VDDQ and VSSQ are supplied to the input/output circuit 122. The power supply potentials VDDQ and VSSQ supplied to the power supply terminals may be the same potentials as the power supply potentials VDD and VSS supplied to the power supply terminals in an embodiment of the disclosure. The power supply potentials VDDQ and VSSQ supplied to the power supply terminals may be different potentials from the power supply potentials VDD and VSS supplied to the power supply terminals in another embodiment of the disclosure. The power supply potentials VDDQ and VSSQ supplied to the power supply terminals are used for the input/output circuit 122 so that power supply noise generated by the input/output circuit 122 does not propagate to the other circuit blocks.

FIG. 2 is a block diagram of a memory device according to some embodiments of the present disclosure. The memory device 200 shows an example layout of certain components which are used as part of access operation in the memory device 200. The memory device 200 may, in some embodiments, be included in the semiconductor device 100 of FIG. 1. The view of FIG. 2 shows a portion of column planes 210-214 and sense amplifiers 220-224 which may be part of a memory bank (e.g., 118 of FIG. 1) along with selected circuits used in the data path such as the ECC circuit 232 (e.g., ECC control circuit 120 of FIG. 1) and IO circuits 234 (e.g., input/output circuit 122 of FIG. 1). For clarity certain circuits and signals have been omitted from the view of FIG. 2.

The memory device 200 is organized into a number of column planes 210-214. Each of the column planes represents a portion of a memory bank. Each column plane 210-214 includes a number of memory cells at the intersection of word lines WL and bit lines. The word lines may be extend across multiple of the column planes 210-214. The bit lines may be grouped together into sets which are activated by a column select signal CS provided by a column decoder (e.g., 110 of FIG. 1).

For the sake of clarity, only a single vertical line is used to represent the bit lines of each column select set in a given column plane, however, there may be multiple bit lines accessed by each CS value in each column plane. For example, each vertical line in the data column planes 210 and 214 may represent 8 bit lines, all accessed in common by a value of CS. Other values may also be used, for example, each vertical line in the parity column plane 212 may represent 6 bit lines, all accessed in common by a value of CS. As used herein, a ‘value’ of CS may refer to a decoded signal provided to sets of bit lines. So a first value may represent a first value of a multibit CS signal, or after decoding a separate binary signal (e.g., a signal line being active). For example, if the column address includes six bits used to specify a value of the CS signal, then the column decoder may decode a value of those six bits of the column address into activating one of 64 different CS signal lines.

The memory device 200 includes a set of data column planes 210 as well as an extra column plane or parity column plane (Parity CP) 212. The extra column plane 212 may be used to store the parity bits. In some embodiments, the memory 200 may also include an optional global column redundancy (GCR) column plane 214. In some embodiments, the GCR plane 214 may have fewer memory cell (e.g., fewer column select groups) than the data column planes 210. The GCR CP 214 includes a number of redundant columns which may be used as part of a repair operation. For example, if a value of the CS signal is identified as including defective memory cells in one of the data column planes 210, then the memory may be remapped such that the information which would have been stored in that column plane for that value of CS is instead stored in the GCR CP 214.

The set of data column planes 210 may include a number of column planes 0 to M. The number of column planes is not limited. The parity column plane 212 may be used to store the default parity bits. In some examples, the parity column plane 212 may include fewer bit lines than the data column planes 210. As shown in FIG. 2, the column set 0 (CS 0) of column plane 210(0) may include word lines WL0 to WLJ and bit lines BL0 to BLN; the column set 0 of the parity CP 212 may include word lines WL0 to WLJ and bit lines BL0 to BLP, where N is different than P. In an example, N may be greater than P. The different between the number of bit lines may be based, in part, on a difference between the number of bit lines activated by the CS signal in each column plane 210 and 212, For example, if a CS value activates A bit lines in the data column planes 210 and activates B bit lines in the parity column plane 212, then the parity column plane 212 may have B/A as many bit lines (e.g., B/A as many memory cells) as one of the data column planes 210.

An example memory device 200 according to some embodiments of the present disclosure may include a plurality of data column planes 210(0)-210(M). In an example where there are 32 column planes, organized in 2 sets of 16 column planes. In this embodiment, M may be 31. However, M is not limited to 31. Each of those data column planes 210 includes 64 sets of bit lines (e.g., CS sets) activated by a value of the column select signal, and each set of bit lines includes 8 bit lines. Accordingly, when a word line is opened responsive to a row address, and a column select signal is provided to each of the 32 column planes then 8 bits are accessed from each of the 32 column planes for a total of 256 bits. The column select signal is also provided to the parity CP 212. While a single parity column plane is shown in FIG. 2, there may be two parity column planes 212, one for each set of 16 data column planes (e.g., the dashed parity column plane 212). Each parity column plane 212 includes a different number of bit lines associated with the value of CS than in the data column planes 210. For example, each parity column plane 212 may access 6 bit lines for a value of CS, for a total of 256 data bits and 12 parity bits per access operation. In some examples, each column select signal in the column planes 210 may be coupled to 8 bit lines and 8 IOs, and each column select signal in the column plane 212 may be coupled to 6 bit lines and 6 IOs.

If a repair operation has been performed, the GCR CP 214 may also be accessed and the information accessed in the GCR CP 214 may be swapped for the information accessed from the repaired CP (e.g., by multiplexing a GCR local input/output line onto the repaired LIO line). The repairs may generally be performed on a CS set by CS set basis, with the entire CS set which includes a bit line error being repaired. In some examples, when a bit line parity from the parity CP 212 is to be repaired, remapping may be done to account for the different bit lines in parity CP. For example, when repairing the CS coupled with 6 bit lines, data steering may result in masking, or not using 2 extra bits from in GRC CP 214. For the sake of consistency, reference will generally be made throughout to these example values, however, it should be understood that embodiments of the present disclosure may have a different architecture, which involves more or fewer column planes, more or fewer bit lines per CS set, more or fewer, CS sets per column plane, and so forth.

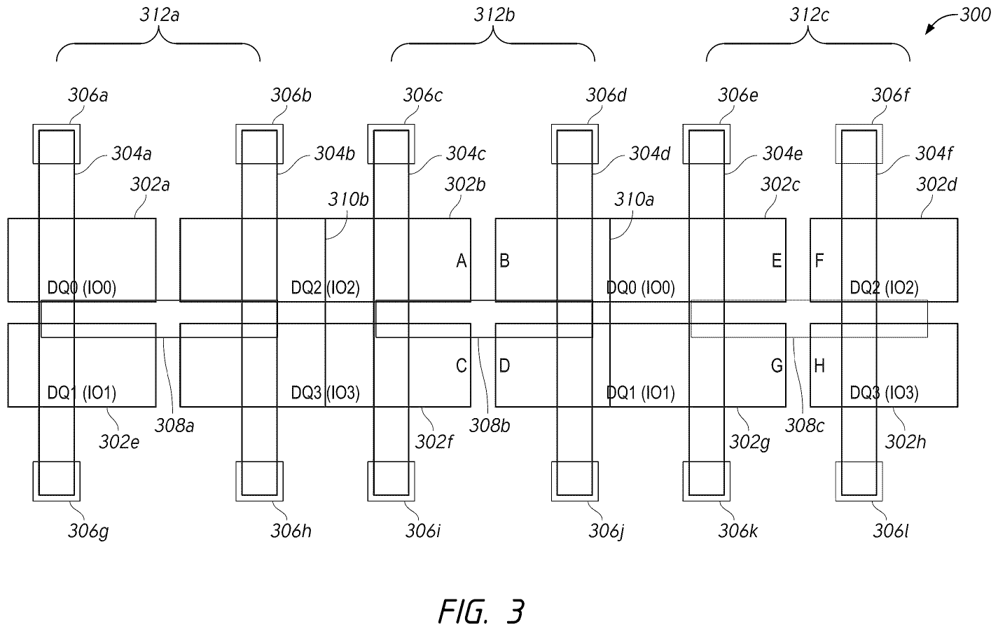

FIG. 3 shows a layout of a set of transfer gates 300 that includes a data column plane that receives a CS signal coupled to 8 bit lines according to an embodiment of the disclosure. The transfer gates 300 may, in some embodiments, be included in the memory array 118 of FIG. 1, and/or coupled to the data column planes 210 of FIG. 2.

The memory array may generally be arranged in ‘mats’ or ‘sections’ with a block of memory cells in the section surrounded on either side by a first sense amplifier region and a second sense amplifier region. The sense amplifier regions may generally be referred to as even or odd regions, as each region may couple to either even or odd bit lines in the two sections adjacent to the region. The regions include the sense amplifiers as well as various other components, such as the transfer gates. The transfer gates 300 of FIG. 3 may represent a portion of the transfer gates in a sense amplifier region which couple bit lines to local input/output lines for one of the adjacent memory cell sections. Accordingly, the view of FIG. 3 may represent half of the bit lines which are activated by a value of a CS signal.

The transfer gates 300 may be shown as a plurality of boxes 302a to 302h which represent connections between a with a plurality of local input/output lines (LIOs). Digit lines A to H are shown in boxes 302b, 302c, 302d, 302f, 302g, and 302h. The following discussion will be made regarding to digit lines A to H, however, the discussion should not be interpreted as limiting to only boxes 302b, 302c, 302d, 302f, 302g, and 302h.

As shown in FIG. 3, digit lines B and E share box 302c because the box 302c is coupled to a common LIO line. Digit lines D and F share box 302g because the box 302g is coupled to a common LIO line. For example, when activated, digit line B or digit line E may be coupled to DQ0 via LIO line 310a; when activated, digit line D or digit line F may be coupled to DQ1 via LIO line 310b. When activated, the digit lines in box 302b may be coupled to DQ2 via LIO line 310b. When activated, the digit lines in box 302f may be coupled to DQ3 via LIO line 310b.

Boxes 302a, 302b, 302c, and 302d are arranged along a first direction. Boxes 302a, 302b, 302c, 302d may be opposite boxes 302e, 302f, 302g, 302h, respectively, in a second direction orthogonal to the first direction. The boxes 302e, 302f, 302g, 302h are arranged along the first direction.

A gate structure 312 may be H shaped and may include gate elements 304 and 308. Gate elements 304 and 308 forming a single H shape structure may have gate elements 304 extending in the second direction and the gate elements 308 extending in the first direction and respectively coupled between the gate structures 304. For example, gate structure 312a includes gate elements 304a, 304b and 308a, and gate element 308a is coupled to the gate elements 304, 304b. Gate structure 312b includes gate elements 304c, 304d, and 308b, and gate element 308b is coupled to the gate elements 304c, 304d. Gate structure 312c includes gate elements 304c, 304f, and 308c, and gate element 308c is coupled to the gate elements 304e, 304f. The gate structures 304 and 308 may be made of conductive material.

Each gate element 304 is coupled to two respective external connections 306 at opposite ends in the second direction. As shown in FIG. 3, the gate element 304a is coupled to external connection 306a and external connection 306g; the gate element 304b is coupled to external connection 306b and external connection 306h; the gate element 304c is coupled to external connection 306c and external connection 306i; the gate element 304d is coupled to external connection 306d and external connection 306j; the gate element 304e is coupled to external connection 306e and external connection 306k; and the gate element 304f is coupled to external connection 306f and external connection 306l. In an example, one of the external connections 306 is configured to receive a CS signal.

Gate element 304a extends in the second direction and overlaps with the boxes 302a and 302c. Gate elements 304b and 304c extend in the second direction and overlap with the boxes 302b and 302f. Gate elements 304d and 304e extend in the second direction and overlap with the boxes 302c and 302g. A gate element 304f extends in the second direction and overlaps with the boxes 302d and 302h.

In a read operation, the 8-bit read data may be read from boxes 302 (302a-302h) via gate structures 312 made of gate elements 304 (304a-304f) and 308 (308a-308c) to external connections 306 (306a-3061). The transfer gates 300 may couple the digit lines to respective gates which lead to an ECC control circuit (not shown). Conversely, in a write operation, the 8-bit write data may be received by the external connections 306 and transferred to the respective one of digit lines in boxes 302 via respective gates made of gate elements 304 and 308. In some examples, external connections 306 may be made of conductive material.

In an example of an operation involving a gate made of gate structures 304a, 304b and 308a, only one of external connections 306a, 306b, 306g, and 306h is electrically connected to the respective column select line. In another example of an operation involving a gate structure 312b made of gate elements 304c, 304d, and 308b, only one of external connections 306c, 306d, 306i, and 306j is electrically connected to the respective column select line. In another example of an operation involving a gate structure 312c made of gate elements 304c, 304f, and 308c, only one of external connections 306e, 306f, 306k, and 306l is electrically connected to the respective column select line.

FIG. 3 is described with respect to an example embodiment where there are 32 data column planes, organized in 2 sets of 16 column planes. Each of the data column planes includes 64 sets of bit lines (e.g., CS sets) each of which provides 8 bits of data when activated by the respective CS signal. It should be understood that this is one example implementation of the present disclosure, and that other arrangements may be used in other example embodiments (e.g., more or fewer CS sets per CP, more or fewer CP's per memory bank, etc.).

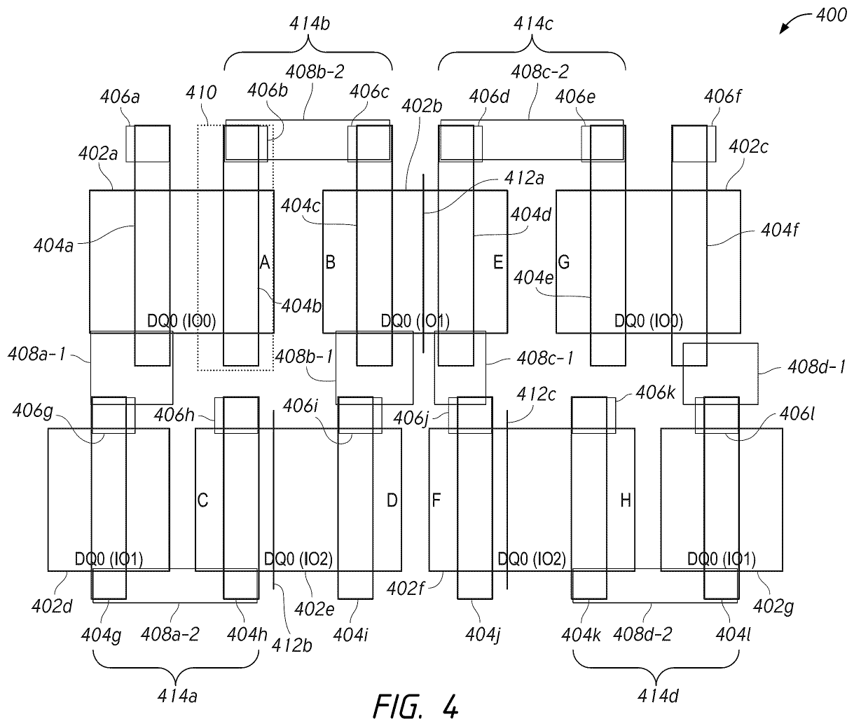

FIG. 4 shows a layout of a plurality of transfer gates 400 that is coupled to a parity column plane that receives a CS signal coupled with 6 bit lines according to an embodiment of the disclosure. The transfer gates 400 may, in some embodiments, be included in the memory array 118 of FIG. 1. The parity column plane may include the parity column planes 212 of FIG. 2.

The transfer gates 400 may include a plurality of boxes 402a to 402g via a plurality of local input/output lines (LIOs). Digit lines A to H are shown in boxes 402a to 402c and boxes 402e to 402f. The following discussion will be made regarding to digit lines A to H. However, the discussion should not be interpreted as limiting only boxes 402a to 402c and boxes 402e to 402f.

As shown in FIG. 4, digit lines B and E share box 402b because the box 402b is coupled to LIO line 412a. Digit lines C and D share box 402e because the box 402e is coupled to LIO line 412b. Digit lines F and H share box 402f because the box 402f is coupled to LIO line 412c. For example, when activated, digit line B or digit line E may be coupled to DQ1 via LIO line 412a; when activated, digit line C or digit line D may be coupled to DQ2 via LIO line 412b. When activated, the digit line F or digit line H may be coupled to DQ2 via LIO line 412c. Other digit lines in other boxes may couple to the respective DQ in similar manners.

Boxes 402a, 402b, and 402c are arranged along a first direction. Boxes 402d, 402c, 402f, and 402g are arranged along the first direction. The boxes 402d, 402c, 402f, and 402g may be opposite boxes 402a, 402b, and 402c in a second direction orthogonal to the first direction.

A gate structure 414 may have an “L” shape (e.g. 414a, 414c) or an inverted “L” shape (e.g. 414b, 414d) and may include gate elements 404 and 408. For example, gate structure 414a includes gate elements 404a, 404g, 404h, 408a-1, and 408a-2. Gate structure 414b includes gate elements 404b, 404c, 404i, 408b-1, and 408b-2. Gate structure 414c include gate elements 404d, 404c, 404j, 408c-1, and 408c-2. Gate structure 414d includes gate elements 404f, 404k, 4041, 408d-1, and 408-d2.

In some examples, in gate structure 414a, gate elements 404a, 404g, 404h may be connected by the gate elements 408a-1 and 408a-2 to form an “L” shape. In gate structure 414b, gate elements 404b, 404c, 404i may be connected by gate elements 408b-1 and 408b-2 to form an inverted “L” shape. The gate element 408a-1 of the gate structure 414a is adjacent to the gate element 408b-1 of the gate structure 414b in the first direction. The gate elements 408a-1 and 408a-2 of the gate structure 414a and the gate elements 408b-1 and 408b-2 of the gate structure 414b are arranged in a flip flop pattern such that the gate element 408a-2 of the gate structure 414a and the gate element 408b-2 of the gate structure 414b are across from each other distanced by boxes 402a, 402d, 402e. A similar pattern may be observed for gate structures 414c and 414d.

Gate elements 408 (e.g. 408a-d) are coupled to neighboring gate elements 404 overlapping with respective digit lines to form a gate structure. The gate elements 408 (e.g. 408a-d) may be implemented by gate elements 308 of FIG. 3. In some examples, gate structure 414a may include gate elements 408a-1 and 408a-2. The gate element 408a-1 is coupled to gate element 404a, gate element 404g, and external connection 406g. The gate element 408a-2 is coupled to neighboring gate elements 404g and 404h. Gate structure 414b may gate elements 408b-1 and 408b-2. Gate element 408b-1 is coupled to gate element 404c, gate element 404i, and external connection 406i. Gate element 408b-2 is coupled to neighboring gate elements 404b and 404c, and external connections 406b and 406c. Gate structure 414c may include gate elements 408c-1 and 408c-2. Gate element 408c-1 is coupled gate elements 404d, 404j, and external connection 406j. Gate element 408c-2 is coupled to neighboring gate elements 404d and 404c, and external connections 406d and 406c. Gate structure 414d may include gate elements 408d-1 and 408d-2. The gate element 408d-1 is coupled to gate elements 404f and 404l, and external connection 406l. The gate element 408d-2 is coupled to neighboring gate elements 404k and gate structure 4041.

Gate elements 404a and 404b extend in the second direction and overlap with box 402a. Gate elements 404c and 404d extend in the second direction and overlap with box 402b. Gate elements 404c and 404f extend in the second direction and overlap with the box 402c. Gate element 404g extends in the second direction and overlaps with box 402d. Gate elements 404h and 404i extend in the second direction and overlap with box 402e. Gate elements 404j and 404k extend in the second direction and overlap with box 402f. Gate element 404l extends in the second direction and overlaps with box 402g. In some examples, the gate elements 404a to 4041 in FIG. 4 may be shorter than the gate elements 304a-304f in FIG. 3.

Each gate element 404 of gate structures 414 is coupled to a respective external connection 406. External connections 406 may be implemented by the external connections 306 of FIG. 3. In an example, one of the external connections 406 is configured to receive a CS signal.

As shown in FIG. 4, an active area 410 may be formed over box 402a, around gate element 404b, external connection 406b. Although for simplicity, only one active area 410 is shown in FIG. 4, more active areas may be formed on the box 402a and/or other boxes box 402b to 402g. The active area may be implemented as a common source or drain region.

In a read operation, the 6-bit read parity information may be read from boxes 402 (402a to 402g) via gate elements 404 (404a-4041) to external connections 406 (406a-4061). The transfer gates 400 may be coupled to an ECC control circuit (not shown). Conversely, in a write operation, the 6-bit write parity information may be received by the external connections 406 and transferred to respective ones of digit lines in boxes 402 and via gate elements 404.

In an example of an operation involving gate elements 404a, 404g, and 404h that are connected by gate element 408a, only one of external connections 406a, 406g, and 406h is electrically connected to the respective column select line. In another example of an operation involving gate elements 404b 404c, 404i that are connected by gate element 408b, only one of external connections 406b, 406c, and 406i is electrically connected to the respective column select line. In another example of an operation involving gate elements 404d, 404c, and 404j that are connected by gate element 408c, only one of external connections 406d, 406c, and 406j is electrically connected to the respective column select line. In another example of an operation involving gate elements 404f, 404k, and 404l that are connected by gate element 408d, only one of external connections 406f, 406k, and 406l is electrically connected to the respective column select line.

FIG. 4 is described with respect to an example embodiment where there are 32 data column planes, organized in 2 sets of 16 column planes. Each of the data column planes includes 64 sets of bit lines (e.g., CS sets) each of which provides 6 bits of parity information when activated by the respective CS signal. It should be understood that this is one example implementation of the present disclosure, and that other arrangements may be used in other example embodiments (e.g., more or fewer CS sets per CP, more or fewer CP's per memory bank, etc.).

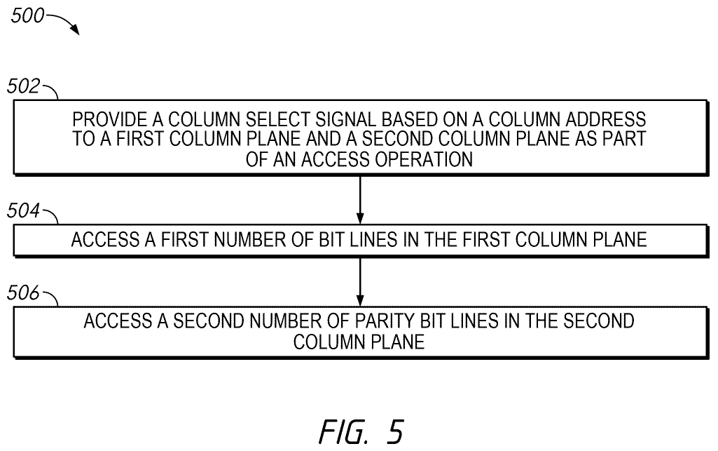

FIG. 5 is a flow chart of a method of reading data and default parity according to some embodiments of the present disclosure. The method 500 may, in some embodiments, be implemented by one or more of the systems or apparatuses described herein. For example, the method 500 may be performed by the semiconductor device 100 of FIG. 1 or memory device 200 of FIG. 2. The method 500 may be used to retrieve data, such as the data written based on the write operation described in FIG. 3 and FIG. 4. For the sake of brevity, certain operations described with respect to FIG. 3, such as enabling extra parity with a mode register, are not repeated with respect to FIG. 4.

The method 500 includes box 502 which provides a column select signal based on a column address to a first column plane and a second column plane as part of an access operation. The first column plane may be implemented by transfer gates 300 of FIG. 3. The second column plane may be implemented by transfer gates 400 of FIG. 4.

Box 502 may be followed by box 504. Box 504 may be followed by box 506. Box 504 describes accessing a first number of bit lines from the first column plane as part of an access operation (e.g. read or write operation). Box 506 describes accessing a second number of parity bit lines from the second column plane as part of the access operation. In some examples, the first number and the second number are different. The first number may be greater than the second number.

In some embodiments, the method 500 may further include locating an error, correcting the error, or combinations thereof in the bit lines in the first column plane based on the parity bit lines with an error correction code (ECC) circuit. The ECC circuit may be implemented by ECC control circuit 120 of FIG. 1 and/or ECC circuit 232 of FIG. 2. The ECC circuit may perform single error correction double error detection (SECDED) as described above in relation to FIG. 2.

In some examples, if the access operation is a read operation, the read operation may include amplifying, by a sense amplifier, read data from a bit line in the first column plane. The amplification of the read data may be based on a column select signal. The sense amplifier may be implemented by the SAMP in FIG. 1, and/or sense amplifiers 220 of FIG. 2. The ECC circuit may transfer the amplified read data to an input/output (I/O) circuit. The I/O circuit may be implemented by the input/output circuit 122 of FIG. 1, and/or the IO circuit 234 of FIG. 2.

In other examples, if the access operation is a write operation, the write operation may include transferring write data from the ECC circuit. The write operation may further include writing the write data in a memory cell coupled to an associated bit line in the first column plane. The memory cell may be implemented by memory array 118 of FIG. 1 and/or memory device 200 of FIG. 2. The write operation may further include generating parity bits based on the write data and providing the parity bits by the ECC circuit to the memory bank.

Of course, it is to be appreciated that any one of the examples, embodiments or processes described herein may be combined with one or more other examples, embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a first column plane comprising a first number of a first plurality of bit lines associated with a column select signal;
a second column plane comprising a second number of a second plurality of bit lines associated with the column select signal; and
a column decoder configured to provide the column select signal and activate the first number of the first plurality of bit lines in the first column plane and the second number of the second plurality of bit lines in the second column plane, wherein the first number activated is different than the second number activated, wherein the first column plane is configured to store data and the second column plane is configured to store parity bits.

2. The apparatus of claim 1, further comprising:
an error correction code (ECC) circuit configured to detect and correct an error based on the data and the parity bits.

3. The apparatus of claim 1, further comprising:
a first gate structure coupled to a first bit line and a second bit line of the second plurality of bit lines,
wherein the first bit line and the second bit line are adjacent to each other in a first direction, and
wherein the first gate structure comprises a first gate element, a second gate element, and a third gate element.

4. The apparatus of claim 3,
wherein the first gate structure comprises a fourth gate element and a fifth gate element,
wherein the fourth gate element is disposed between the second gate element and the third gate element,
wherein the second gate element and the third gate element are arranged in a second direction orthogonal to the first direction,
wherein the fifth gate element is coupled to the third gate element and another gate element of a second gate structure,
wherein the third gate element and the other gate element are arranged on opposite sides in a second direction, the second direction orthogonal to the first direction.

5. The apparatus of claim 1, further comprising a third column plane including the first number of a third plurality of bit lines associated with a column signal associated with a defective memory cell in one of the first column plane and the second column plane.

6. The apparatus of claim 1, wherein the first number of the first plurality of bit lines activated by the column select signal is greater than the second number of the second plurality of bit lines activated by the column select signal.

7. The apparatus of claim 6, wherein the first number is 8 and the second number is 6.

8. An apparatus comprising:
a memory bank comprising:
a plurality of first column planes, each first column plane comprising a first plurality of bit lines;
a second column plane comprising a second plurality of bit lines; and
a third column plane including a third plurality of bit lines associated with a column signal associated with a defective memory cell in one of the first column plane and the second column plane;
a column decoder configured to receive a column address and provide a column select signal in an access operation based on the column address to the plurality of first column planes and the second column plane; and
an ECC circuit configured to locate and correct errors based on data and parity bits from a plurality of bit lines,
wherein a first number of the first plurality of bit lines activated in response to the column select signal is different from a second number of the second plurality of bit lines activated in response to the column select signal,
wherein a third number of the third plurality of bit lines is the same as the number of the first plurality of bit lines.

9. The apparatus of claim 8,
a first plurality of local input/output (LIO) lines coupled to a column plane of the plurality of first column planes;
a second plurality of LIO lines coupled to the second column plane.

10. The apparatus of claim 9, further comprising:
a plurality of sense amplifiers coupled to the memory bank and configured to communicate data between the memory bank and the ECC circuit;
a transfer gate; and
a plurality of global input/output (GIO) lines coupled to the plurality of first column planes and the second column plane.

11. The apparatus of claim 10, wherein the access operation is a read operation, and wherein in the read operation:
a sense amplifier of the plurality of sense amplifiers is configured to amplify read data from a respective bit line in the first column plane and transfer amplified read data to the plurality of GIO lines via the ECC circuit over the first plurality of LIO lines and the transfer gate.

12. The apparatus of claim 10, wherein the access operation is a write operation, and wherein in the write operation:
the ECC circuit is configured to output write data to a sense amplifier of the plurality of sense amplifiers over the plurality of GIO lines, the transfer gate, and the plurality of LIO lines; and
the write data is written in the memory bank coupled to a bit line associated with the sense amplifier.

13. The apparatus of claim 8, wherein the first number of the first plurality of bit lines is greater than the second number of the second plurality of bit lines.

14. A method comprising:
providing a column select signal based on a column address to a first column plane and a second column plane as part of an access operation;
accessing a first number of a first plurality of bit lines in the first column plane; and
accessing a second number of a second plurality of bit lines in the second column plane, wherein the first number and the second number are different.

15. The method of claim 14, further comprising:
locating an error, correcting the error, or combinations thereof in the first plurality of bit lines in the first column plane based on the second plurality of bit lines with an error correction code (ECC) circuit.

16. The method of claim 15, wherein the access operation is a read operation, the read operation comprises:
amplifying, by a sense amplifier, read data from a bit line of the first plurality of bit lines in the first column plane;
transferring the amplified read data to an input/output circuit via the ECC circuit.

17. The method of claim 15, wherein the access operation is a write operation, the write operation comprises:
transferring write data from the ECC circuit; and
writing the write data in a memory cell coupled to an associated bit line of the first plurality of bit lines in the first column plane.

18. The method of claim 17, wherein the write operation further comprises:
generating parity bits based on the write data; and
providing the parity bits by the ECC circuit to the memory cell.

19. The method of claim 14, wherein the first number is greater than the second number.

20. The method of claim 14, further comprising:
providing a second column select signal based on a defective column address to one of the first column plane and the second column plane as part of a second access operation;
accessing the first number of a third plurality of bit lines in a third column plane responsive to the second column signal being provided to the first column plane; and
accessing the second number of the third plurality of bit lines in the third column plane responsive to the second column signal being provided to the second column plane.
